(19) United States
(12) Patent Application Publication
(10) Pub. No.: US 2026/0018233 A1
(43) Pub. Date: Jan. 15, 2026

(54) TEST DEVICE FOR TESTING STORAGE DEVICE, TEST RACK, AND TEST SYSTEM INCLUDING TEST DEVICE

(71) Applicant: SAMSUNG ELECTRONICS CO., LTD., Suwon-si (KR)

(72) Inventors: Kwangkyu Bang, Suwon-si (KR); Jaegyu Choi, Suwon-si (KR)

(73) Assignee: SAMSUNG ELECTRONICS CO., LTD., Suwon-si (KR)

(21) Appl. No.: 19/176,866

(22) Filed: Apr. 11, 2025

(30) Foreign Application Priority Data
Jul. 11, 2024 (KR) 10-2024-0091977

(51) Int. Cl. G11C 29/56; H05K 7/20

(52) U.S. Cl. CPC G11C 29/56016; H05K 7/20172; H05K 7/20336; H05K 7/205; G11C 2029/5602

(57) ABSTRACT

Provided is a test device including a supporter, a test board on the supporter, the test board including a central processing unit (CPU) and a plurality of ports connected to the CPU through a plurality of lanes respectively on different side surfaces of the test board and having different lengths, and a rotator between the supporter and the test board, the rotator being configured to rotate the test board with respect to a rotation axis perpendicular to an upper surface of the test board.

### CROSS-REFERENCE TO RELATED APPLICATION

This application claims priority to Korean Patent Application No. 10-2024-0091977 filed in the Korean Intellectual Property Office on Jul. 11, 2024, the entirety of which is incorporated herein by reference.

### BACKGROUND

The present disclosure relates to a test system that includes a test device, a test rack, and a test device for testing storage devices.

Peripheral component interconnect express (PCIe) 6.0 adopted the pulse amplitude modulation 4-levels (PAM-4) method instead of the non return to zero (NRZ) method as data signal transfer method in order to increase the data transfer rate. In PAM-4, signal integrity is important because the information represented by the data signal varies depending on the level of the data signal. Since a storage device such as a solid state drive (SSD) is used by being connected to lanes of various lengths depending on the environment, the signal integrity of the storage device needs to be tested by being connected to lanes of various lengths.

### SUMMARY

One or more embodiments provide a test device, a test rack and a test system for testing a storage device connected to lanes of various length.

According to an aspect of one or more embodiments, there is provided a test device including a supporter, a test board on the supporter, the test board including a central processing unit (CPU) and a plurality of ports connected to the CPU through a plurality of lanes respectively on different side surfaces of the test board and having different lengths, and a rotator between the supporter and the test board, the rotator being configured to rotate the test board with respect to a rotation axis perpendicular to an upper surface of the test board.

According to another aspect of one or more embodiments, there is provided a test system including a storage device, and a test device including a plurality of ports on different side surfaces of the test board and connected to a plurality of lanes having different lengths, respectively, the test device being configured to test the storage device sequentially connected to the plurality of ports.

According to still another aspect of one or more embodiments, there is provided a test rack including a supporter, a main body case including a plurality of open side surfaces, the main body being on the supporter, a rack portion included in the main body case and including a test board that includes a plurality of ports respectively on the plurality of open side surfaces and respectively connected to a plurality of lanes having different lengths, and a rotator between the supporter and the main body case, the rotator being configured to rotate the main body case with respect to a rotation axis perpendicular to an upper surface of the main body case.

### BRIEF DESCRIPTION OF DRAWINGS

Embodiments will be more clearly understood from the following detailed description taken in conjunction with the accompanying drawings in which:

FIG. 1 is a drawing illustrating a test device according to one or more embodiments;

FIG. 2 is a drawing illustrating a test board according to one or more embodiments;

FIGS. 3 and 4 are drawings illustrating the arrangement of the central processing unit (CPU), power management unit (PMU), baseboard management controller (BMC) in a chipset according to one or more embodiments.

FIG. 5 is a drawing illustrating an auxiliary heatsink according to one or more embodiments, which is connected to a CPU cooler;

FIG. 6 is a drawing to illustrating a rotator including an internal fan according to one or more embodiments;

FIG. 7 is a drawing illustrating a thermal pad disposed on the rotator according to one or more embodiments;

FIG. 8 is a drawing illustrating the structure of a test device according

to one or more embodiments;

FIG. 9 is a drawing illustrating a test rack where a test device according to one or more embodiments are disposed;

FIG. 10 is a drawing illustrating a test system testing a storage device connected to a first port disposed on a first side surface of the test board, according to one or more embodiments;

FIG. 11 is a drawing illustrating a test system testing a storage device connected to a second port disposed on a second side surface of the test board, according to one or more embodiments;

FIG. 12 is a drawing illustrating a test system testing a storage device connected to a third port disposed on a third side surface of the test board, according to one or more embodiments;

FIG. 13 is a drawing illustrating a test board disposed on a rotating test rack according to one or more embodiments;

FIG. 14 is a drawing illustrating a storage device connected to a test board disposed on a rotating test rack, according to one or more embodiments;

FIG. 15 is a drawing illustrating a test board according to one or more embodiments in which a plurality of ports connected to a plurality of lanes having different lengths are disposed on one side surface; and

FIG. 16 is a flowchart illustrating a test device for testing a storage device according to one or more embodiments.

### DETAILED DESCRIPTION

Hereinafter, with reference to accompanying drawings, various embodiments of the present disclosure will be described in detail so that a person of an ordinary skill may easily implement the present disclosure. The present disclosure may be implemented in many different forms and is not limited to the embodiments described herein.

In order to clearly explain the present disclosure, parts that are not relevant to the description are omitted, and identical or similar components are assigned the same reference numerals throughout the specification.

In addition, the size and thickness of each component shown in the drawings are shown arbitrarily for convenience of explanation, so the present disclosure is not necessarily limited to what is shown. In the drawings, the thickness of layers, films, panels, regions, etc., are exaggerated for clarity. And in the drawings, for convenience of explanation, the thicknesses of some layers and regions are exaggerated.

It will be understood that when an element such as a layer, film, region, or substrate is referred to as being “on” another element, it may be directly on the other element or intervening elements may also be present. In contrast, when an element is referred to as being “directly on” another element, there are no intervening elements present. In addition, being “on” or “above” a reference element means being positioned on or below the reference element, and does not necessarily mean being positioned “above” or “on” in a direction opposite to gravity.

In addition, unless explicitly described to the contrary, the word “comprise”, and variations such as “comprises” or “comprising”, will be understood to imply the inclusion of stated elements but not the exclusion of any other elements.

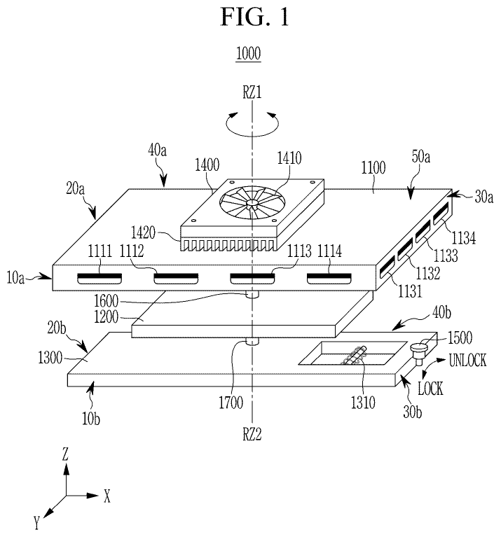

FIG. 1 is a drawing illustrating a test device according to one or more embodiments.

Referring to FIG. 1, the test device 1000 may include a test board 1100, a rotator 1200, a supporter 1300, a CPU cooler 1400, a locker 1500, a first connector 1600, and a second connector 1700.

In one or more embodiments, the test board 1100 may be disposed on the rotator 1200 and the supporter 1300. The rotator 1200 may be disposed between the supporter 1300 and the test board 1100.

In one or more embodiments, the test board 1100 may have a shape having a plurality of sides on an XY plane. The test board 1100 may have a plurality of side surfaces corresponding to a plurality of sides on the XY plane. For example, the test board 1100 may have a rectangular shape with four sides on the XY plane. The test board 1100 may have a first side surface 10a, a second side surface 20a, a third side surface 30a, and a fourth side surface 40a corresponding to the four sides. The first side surface 10a and the fourth side surface 40a are parallel to an XZ plane and may extend in an X direction. The second side surface 20a and the third side surface 30a are parallel to a YZ plane and may extend in a Y direction.

In one or more embodiments, the test board 1100 may include a plurality of ports and chipsets. The plurality of ports may be disposed on a side surface of the test board 1100. The plurality of ports may be disposed on at least one of the plurality of side surfaces of the test board 1100. For example, the plurality of first ports 1111, 1112, 1113, 1114 may be disposed on the first side surface 10a of the test board 1100. The plurality of third ports 1131, 1132, 1133, 1134 may be disposed on the third side surface 30a of the test board 1100. The plurality of second ports may be disposed on the second side surface 20a of the test board 1100.

In one or more embodiments, the chipset may include a CPU, a PMU, and a BMC. The chipset may be connected to the plurality of ports disposed on the plurality side of the test board 1100. For example, the chipset may be connected to the plurality of first port, the plurality of second port, and the plurality of third port.

In one or more embodiments, the CPU cooler 1400 may be disposed on the CPU included in a chipset. The CPU cooler 1400 may cool the CPU. The CPU cooler 1400 may include a CPU fan 1410 and a CPU heatsink 1420. The CPU heatsink 1420 may conduct heat generated by the CPU. The CPU fan 1410 may circulate air to dissipate heat conducted to the CPU heatsink 1420 into the atmosphere.

In one or more embodiments, the test board 1100 may be connected to the rotator 1200 through the first connection 1600. The test board 1100 and rotator 1200 may be rotatable.

In one or more embodiments, the rotator 1200 may rotate the test board 1100 counterclockwise or clockwise. In one or more embodiments, the test board 1100 may be rotated counterclockwise or clockwise as the rotator 1200 rotates. In one or more embodiments, the rotator 1200 is perpendicular to a upper surface 50a of the test board 1100, and may rotate the test board 1100 with respect to a rotation axis RZ1-RZ2 parallel to a Z direction.

In one or more embodiments, the rotator 1200 may rotate the test board 1100 so that the first side surface 10a, the second side surface 20a, or the third side surface 30a of the test board 1100 faces the Y direction. In one or more embodiments, the test board 1100 may be rotated so that the first side surface 10a, the second side surface 20a, or the third side surface 30a of the test board 1100 faces the Y direction as the rotator 1200 rotates.

In one or more embodiments, the supporter 1300 may be a shape

having a plurality of sides on the XY plane. The supporter 1300 may have a plurality of side surfaces corresponding to the plurality of sides on the XY plane. The shape of the supporter 1300 may correspond to the shape of the test board 1100. For example, the supporter 1300 may have a rectangular shape having four sides on the XY plane, similar to the shape of the test board 1100. The supporter 1300 may have a first side surface 10b, a second side surface 20b, a third side surface 30b, and a fourth side surface 40b corresponding to the four sides. The first side surface 10b of the supporter 1300 is parallel to the XZ plane and may extend in the X direction. The second side surface 20b and the third side surface 30b of the supporter 1300 are parallel to the YZ plane and may extend in the Y direction.

The rotator 1200 may rotate the test board 1100 so that the first side surface 10a, the second side surface 20a, or the third side surface 30a of the test board 1100 faces the same direction as the first side surface 10b of the supporter 1300. For example, the first side surface 10a, the second side surface 20a, or the third side surface 30a of the test board 1100 and the first side surface 10b of the supporter 1300 may be aligned in the same direction. For example, the first side surface 10a of the test board 1100 and the first side surface 10b of the supporter 1300 may be aligned to face a direction which is perpendicular to the rotation axis RZ1-RZ2 and parallel to the upper surface 50a of the test board 1100. In one or more embodiments, the direction which is perpendicular to the rotation axis RZ1-RZ2 and parallel to the upper surface 50a of the test board 1100 may be the Y direction. In one or more embodiments, the second side surface 20a of the test board 1100 and the first side surface 10b of the supporter 1300 may be aligned to face a direction which is perpendicular to the rotation axis RZ1-RZ2 and parallel to the upper surface 50a of the test board 1100. In one or more embodiments, the third side surface 30a of the test board 1100 and the first side surface 10b of the supporter 1300 may be aligned to face a direction which is perpendicular to the rotation axis RZ1-RZ2 and parallel to the upper surface 50a of the test board 1100.

In one or more embodiments, the supporter 1300 may be connected to the rotator 1200 through a second connector 1700. The locker 1500 may be disposed on the third side surface 30b of the supporter 1300. Inside the supporter 1200, a locking spring 1310, which rotates clockwise or counterclockwise depending on the position of the locker 1500, may be disposed.

In one or more embodiments, the locker 1500 may allow or prevent rotation of the test board 1100 and the rotator 1200. In one or more embodiments, rotation of the test board 1100 and the rotator 1200 may be allowed or prevented depending on the position of the locker 1500.

In one or more embodiments, when the locker 1500 is positioned at one end of the third side surface 30b of the supporter 1300, the locking spring 1310 is rotated counterclockwise and the motion of the test board 1100 and the rotator 1200 may be locked. In one or more embodiments, when the locker 1500 is positioned at one end of the third side surface 30b of the supporter 1300, rotation of the test board 1100 and the rotator 1200 may be prevented.

In one or more embodiments, when the locker 1500 is positioned at the other end of the third side surface 30b of the supporter 1300, the locking spring 1310 is rotated clockwise and the lock of the motion of the test board 1100 and the rotator 1200 may be released. In one or more embodiments, when the locker 1500 is positioned at the other end of the third side surface 30b of the supporter 1300, rotation of the test board 1100 and the rotator 1200 may be allowed.

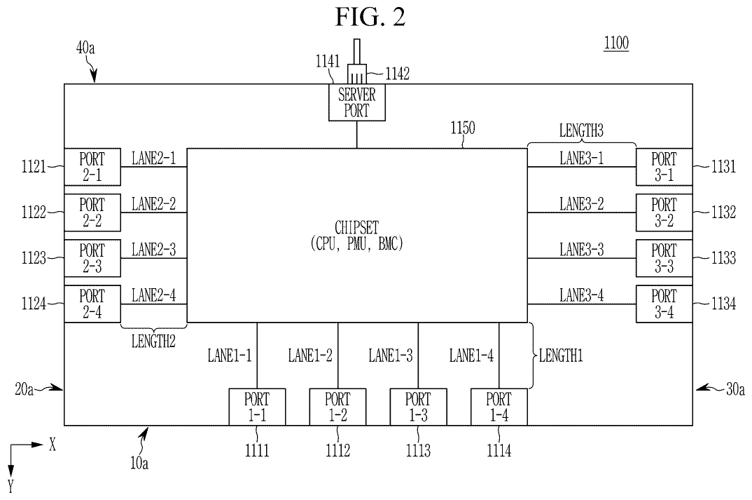

FIG. 2 is a drawing illustrating a test board according to one or more embodiments.

Referring to FIG. 2, the test board 1100 may include a plurality of first ports 1111, 1112, 1113, 1114, a plurality of second ports 1121, 1122, 1123, 1124, a plurality of third ports 1131, 1132, 1133, 1134, a server port 1141, and a chipset 1150. The chipset 1150 may include a CPU, a PMU, and a BMC. The plurality of first ports 1111, 1112, 1113, 1114, the plurality of second ports 1121, 1122, 1123, 1124, the plurality of third ports 1131, 1132, 1133, 1134, the server port 1141, and the chipset 1150 may be disposed on a printed circuit board (PCB) of the test board 1100.

In one or more embodiments, the plurality of first ports 1111, 1112, 1113, 1114, the plurality of second ports 1121, 1122, 1123, 1124, and the plurality of third ports 1131, 1132, 1133, 1134 may be connected to the CPU included in the chipset 1150 through a plurality of lanes or a plurality of channels having different lengths.

In one or more embodiments, the plurality of first ports 1111, 1112, 1113, 1114 may be disposed on the first side surface 10a of the test board 1100. The plurality of first ports 1111, 1112, 1113, 1114 may be respectively connected to the CPU included in the chipset 1150, through a first lanes LANE1-1, LANE1-2, LANE1-3, LANE1-3, LANE1-4 having a first length LENGTH1 in the Y direction. In one or more embodiments, the plurality of first ports 1111, 1112, 1113, 1114 may include a 1-1st port 1111, a 1-2nd port 1112, a 1-3rd port 1113, and a 1-4th port 1114. The first lanes LANE1-1, LANE1-2, LANE1-3, LANE1-4, may include a 1-1st lane LANE1-1, a 1-2nd lane LANE1-2, and a 1-3rd lane LANE1-3 and a fourth lane LANE1-4.

In one or more embodiments, the 1-1st port 1111, the 1-2nd port 1112, the 1-3rd port 1113, and the 1-4th 4 port 1114 disposed on the first side surface 10a of the test board 1100 may respectively connected to the CPU included in the chipset 1150, the 1-1st lane LANE1-1, the 1-2nd lane LANE1-2, 1-3rd lane LANE1-3, and 1-4th lane LANE1-4 having the first length LENGTH1.

In one or more embodiments, the plurality of second ports 1121, 1122, 1123, 1124 may be disposed on the second side surface 20a of the test board 1100. The plurality of second ports 1121, 1122, 1123, 1124 may be connected to the CPU included in the chipset 1150, through the second lanes LANE2-1, LANE2-2, LANE2-3, LANE2-4 having a second length LENGTH2 in the X direction smaller than the first length LENGTH1 in the Y direction. In one or more embodiments, the plurality of second ports 1121, 1122, 1123, 1124 may include a 2-1st port 1121, a 2-2nd port 1122, a 2-3rd port 1123, and a 2-4th port 1124. The second lanes LANE2-1, LANE2-2, LANE2-3, LANE2-4 may include a 2-1st lane LANE2-1, a 2-2nd lane LANE2-2, a 2-3rd lane LANE2-3, and a 2-4th lane LANE2-4.

In one or more embodiments, the 2-1st port 1121, the 2-2nd port 1122, the 2-3rd port 1123, and the 2-4th port 1124 disposed on second side surface 20a of test board 1100 may be respectively connected to the CPU included in the chipset 1150, through the 2-1st lane LANE2-1, the 2-2nd lane LANE2-2, the 2-3rd lane LANE2-3, and the 2-4th lanes LANE2-4 having the second length LENGTH2 in the X direction.

In one or more embodiments, the plurality of third ports 1131, 1132, 1133, 1134 may be disposed on the third side surface 30a of the test board 1100. The plurality of third ports 1131, 1132, 1133, 1134 may be connected to the CPU included in the chipset 1150, through the third lanes LANE3-1, LANE3-2, LANE3-3, LANE3-4 having a third length LENGTH3 in the X direction greater than the first length LENGTH1 in the Y direction. In one or more embodiments, the plurality of third ports 1131, 1132, 1133, 1134 may include a 3-1st port 1131, a 3-2nd port 1132, a 3-3rd port 1133, and a 3-4th port 1134. The third lanes LANE3-1, LANE3-2, LANE3-3, LANE3-4 may include a 3-1st lane LANE3-1, a 3-2nd lane LANE3-2, and a 3-3rd lane LANE3-3 and a third lane LANE3-4.

In one or more embodiments, the 3-1st port 1131, the 3-2nd port 1132, the 3-3rd port 1133, and the 3-4th port 1134 disposed on the third side surface 30a of the test board 1100 may respectively connected to the CPU included in the chipset 1150, the 3-1st lane LANE3-1, the 3-2nd lane LANE3-2, and the 3-3rd lane LANE3-3 and the 3-4th lane LANE3-4 having the third length LENGTH3 in the X direction.

In one or more embodiments, the length of the first lanes LANE1-1, LANE1-2, LANE1-3, LANE1-4, the length of the second lanes LANE2-1, LANE2-2, LANE2-3, LANE2-4, and the length of the third lanes LANE3-1, LANE3-2, LANE3-3, LANE3-4 may be determined depending on the material of the PCB of the test board 1100, as shown in Table 1.

TABLE 1

| | Insertion Loss | | length for PCB material | | | |
|---|---|---|---|---|---|---|
| Lane | (IL) | | Megtron-6 series | | FR4 series | |
| second lane | -5 | [dB] | -6.25 | cm | -5 | cm |
| first lane | 5-20 | [dB] | 6.25-25 | cm | 5-20 | cm |
| third lane | 20- | [dB] | 25 | cm- | 20 | cm- |

In one or more embodiments, referring to Table 1, the first lane may be the 1-1st lane LANE1-1, the 1-2nd lane LANE1-2, the 1-3rd lane LANE1-3, or the 1-4th lane LANE1-4. The second lane may be the 2-1st lane LANE2-1, the 2-2nd lane LANE2-2, the 2-3rd lane LANE2-3, or the 2-4th lane LANE2-4. The third lane may be the 3-1st lane LANE3-1, the 3-2nd lane LANE3-2, the 3-3rd lane LANE3-3, or the 3-4th lane LANE3-4.

The insertion loss (IL) of the first lane may be greater than 5 dB and less than 20 dB. The insertion loss (IL) of the second lane may be less than 5 dB. The insertion loss (IL) of the third lane may be greater than 20 dB.

In one or more embodiments, the first lane may be the lane having the first length LENGTH1 in the Y direction. In one or more embodiments, the first length LENGTH1 may be greater than 6.25 cm and smaller than 25 cm when the material of the PCB) is the Megtron-6 series. In one or more embodiments, the first length LENGTH1 may be greater than 5 cm and smaller than 20 cm when the printed circuit board (PCB) material is FR4 series.

The second lane may be a lane having the second length LENGTH2 in the X direction smaller than the first length LENGTH1. In one or more embodiments, the second length LENGTH2 may be smaller than 6.25 cm when the material of the PCB is the Megtron-6 series. In one or more embodiments, the second length LENGTH2 may be smaller than 5 cm when the material of the PCB is FR4 series.

The third lane may be a lane having the third length LENGTH3 in the X direction that is greater than the first length LENGTH1. In one or more embodiments, the third length LENGTH3 may be greater than 25 cm when the material of the PCB is Megtron-6 series. In one or more embodiments, the third length LENGTH3 may be greater than 20 cm when the material of the PCB is FR4 series.

In one or more embodiments, the server port 1141 may be disposed on the fourth side surface 40a of the test board 1100. The server port 1141 may be connected to an external server through a cable 1142. The server port 1141 may provide a request and data received from an external server to chipset 1150.

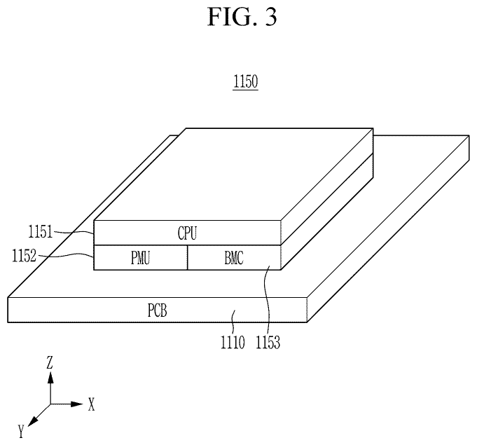

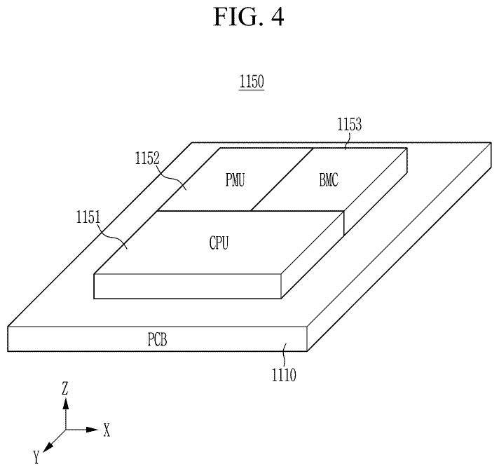

FIGS. 3 and 4 are drawings illustrating the arrangement of the CPU, PMU, and BMC included in the chipset according to one or more embodiments.

First, referring to FIG. 3, the chipset 1150 may include a CPU 1151, a PMU 1152, and a BMC 1153. The chipset 1150 may connected to the plurality of first ports 1111, 1112, 1113, 1114, plurality of second ports 1121, 1122, 1123, 1124, plurality of third ports 1131, 1132, 1133, 1134, and server port 1141 of FIG. 2.

The chipset 1150 may be disposed on a PCB 1110 of the test board 1100. The plurality of first ports 1111, 1112, 1113, 1114, the plurality of second ports 1121, 1122, 1123, 1124, the plurality of third ports 1131, 1132, 1133, 1134, and the server port 1141 may be disposed on the PCB 1110.

In one or more embodiments, CPU 1151 may be disposed on the PCB 1110. A CPU cooler 1400 may be disposed on the CPU 1151. In one or more embodiments, the PMU 1152 and the BMC 1153 may be disposed between the CPU 1151 and the PCB 1110. In one or more embodiments, the CPU 1151 may be disposed on the PMU 1152 and BMC 1153. The PMU 1152 and the BMC 1153 may be disposed on the same plane. In one or more embodiments, the PMU 1152 and the BMC 1153 may be disposed below the CPU 1151.

Next, referring to FIG. 4, the CPU 1151, the PMU 1152, and the BMC 1153 may be disposed on the PCB 1110. In one or more embodiments, the CPU 1151, the PMU 1152, and the BMC 1153 may be disposed on the same plane.

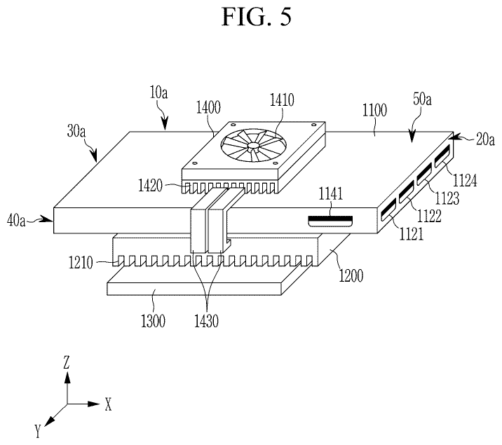

FIG. 5 is a drawing illustrating an auxiliary heatsink according to one or more embodiments, which is connected to a CPU cooler.

Referring to FIG. 5, the rotator 1200 may be disposed on the supporter 1300. The test board 1100 may be disposed on the rotator 1200. The CPU cooler 1400 may be disposed on the CPU 1151 included in the test board 1100.

In one or more embodiments, the CPU cooler 1040 may be connected to the rotator 1200 through a thermal pipe. The CPU cooler 1400 may include a CPU fan 1410 and a CPU heatsink 1420. The rotator 1200 may include an auxiliary heatsink 1210. In one or more embodiments, the CPU heatsink 1420 may be connected to the auxiliary heatsink 1210 through a heat pipe 1430. In one or more embodiments, the heat pipe 1430 may contact the fourth side surface 40a of test board 1100. The server port 1141 may be disposed on the fourth side surface 40a of the test board 1100.

In one or more embodiments, the CPU heatsink 1420 may conduct heat generated from the CPU 1151 to the auxiliary heatsink 1210 through the heat pipe 1430. Since the heat generated from CPU 1151 is conducted to CPU heatsink 1420 and auxiliary heatsink 1210, cooling of the CPU 1151 may be achieved more quickly compared to one or more embodiments of FIG. 1. When the air around the auxiliary heatsink 1210 circulates, heat conducted from the CPU heatsink 1420 to the auxiliary heatsink 1210 through the heat pipe 1430 may be dissipated around the auxiliary heatsink 1210. The test device 1000 according to one or more embodiments may cool the CPU 1151 using the auxiliary heatsink 1210 included in the rotator 1200.

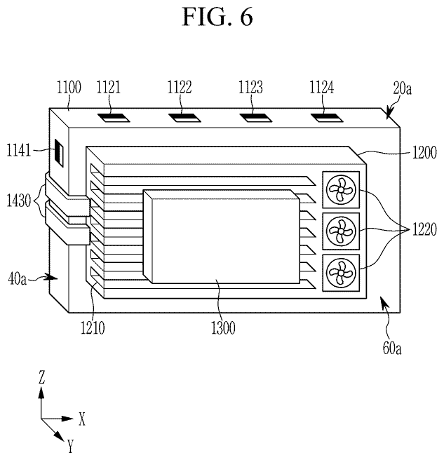

FIG. 6 is a drawing to illustrating a rotator including an internal fan according to one or more embodiments.

Referring to FIG. 6, the rotator 1200 may be disposed on the lower surface 60a of the test board 1100. The supporter 1300 may be disposed below the rotator 1200. The rotator 1200 may include an auxiliary heatsink 1210 and a plurality of internal fans 1220.

In one or more embodiments, the plurality of internal fans 1220 may be disposed adjacent to the CPU 1151 included in the test board 1100. In one or more embodiments, the plurality of internal fans 1220 may be disposed below the CPU 1151 included in the test board 1100. The plurality of internal fans 1220 may reduce the temperature of the CPU 1151 by performing a rotation movement.

In one or more embodiments, heat may be conducted from the CPU heatsink 1420 to the auxiliary heatsink 1210 through the heat pipe 1430. The temperature of the auxiliary heatsink 1210 may increase due to heat conducted from the CPU heatsink 1420. The plurality of internal fans 1220 may circulate air to dissipate heat conducted to the auxiliary heatsink 1210 into the atmosphere. When the temperature of the auxiliary heatsink 1210 decreases, since the heat from the CPU heatsink 1420 is additionally conducted to the auxiliary heatsink 1210 through the heat pipe 1430, cooling of CPU 1151 may be achieved more quickly compared to one or more embodiments of FIG. 5.

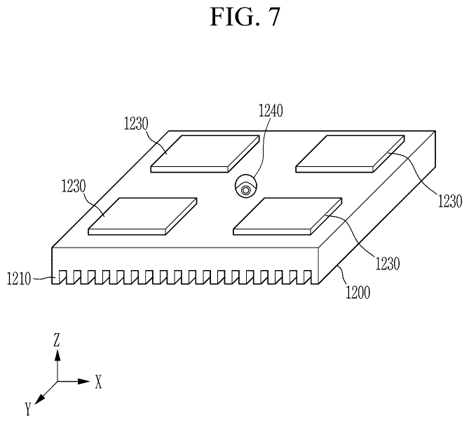

FIG. 7 is a drawing illustrating a thermal pad disposed on the rotator according to one or more embodiments.

Referring to FIG. 7, the rotator 1200 may include an auxiliary heatsink 1210 and a connection groove 1240. The first connector 1600 of FIG. 1 may be disposed at the connection groove 1240. The rotator 1200 may be connected to the test board 1100 through the first connector 1600 of FIG. 1.

In one or more embodiments, a thermal pad 1230 may be disposed on the rotator 1200. The thermal pad 1230 may be disposed between the rotator 1200 and the test board 1100. The thermal pad 1230 may be composed of thermal interface material. The heat pad 1230 may conduct the heat generated from the test board 1100 to the auxiliary heatsink 1210 of the rotator 1200.

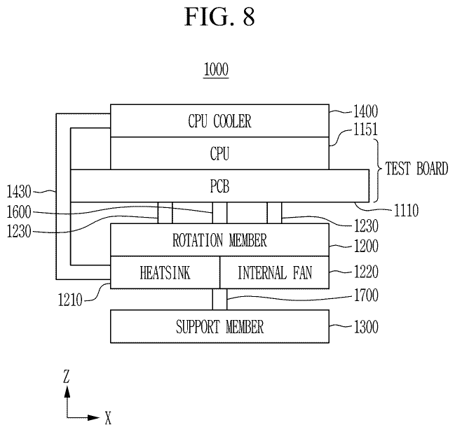

FIG. 8 is a drawing illustrating the structure of a test device according to one or more embodiments.

Referring to FIG. 8, the test device 1000 may include a test board 1100, a rotator 1200, a supporter 1300, a CPU cooler 1400, a first connector 1600, a second connector 1700, a thermal pad 1230, and a heat pipe 1430. The test board 1100 may include a CPU 1151 and a PCB 1110. The rotator 1200 may include an auxiliary heatsink 1210 and a plurality of internal fans 1220.

In one or more embodiments, the rotator 1200 may be disposed on the supporter 1300. The rotator 1200 may be connected to the supporter 1300 through the second connector 1700. The PCB 1110 may be placed on the rotator 1200. The PCB 1110 may be connected to the rotator 1200 through the first connector 1600.

The plurality of internal fans 1220 may be disposed below the CPU 1151. The heat pipe 1430 may be disposed between the PCB 1110 and the rotator 1200.

In one or more embodiments, CPU 1151 may be disposed on the PCB 1110. The CPU cooler 1400 may be disposed on the CPU 1151. The CPU cooler 1400 may be connected to the auxiliary heatsink 1210 through the heat pipe 1430.

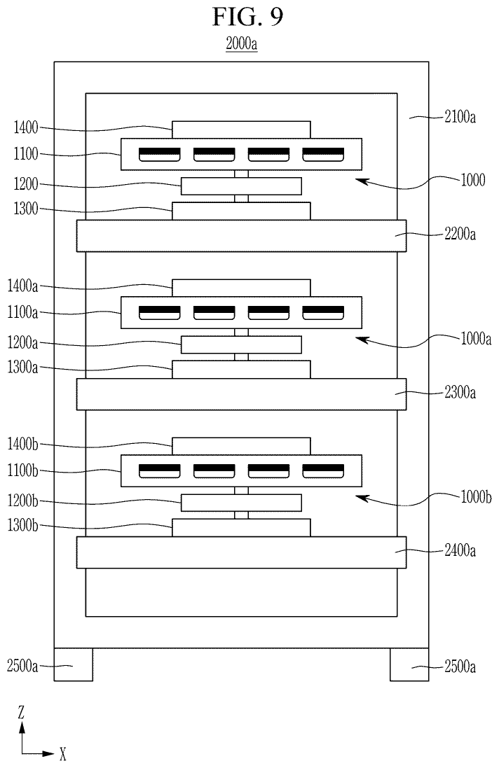

FIG. 9 is a drawing illustrating a test rack where a test device according to one or more embodiments are disposed.

Referring to FIG. 9, a plurality of test devices 1000, 1000a, 1000b may be disposed in the test rack 2000a. The test rack 2000a may include a main body case 2100a, a plurality of rack portions 2200a, 2300a, 2400a, and a supporter 2500a. The plurality of rack portions 2200a, 2300a, 2400a may be disposed inside the main body case 2100a. In one or more embodiments, the plurality of rack portions 2200a, 2300a, 2400a may include a first rack portion 2200a, a second rack portion 2300a, and third rack portion 2400a. The plurality of test devices 1000, 1000a, 1000b may be disposed on the plurality of rack portions 2200a, 2300a, 2400a.

In one or more embodiments, a test device 1000 may be disposed on the first rack portion 2200a. The test device 1000 may include a supporter 1300 disposed on the first rack portion 2200a, a rotator 1200 disposed on the supporter 1300, a test board 1100 disposed on the rotator 1200, and a CPU cooler disposed on the test board 1100.

In one or more embodiments, another test device 1000a may be disposed on the second rack portion 2300a. The test device 1000a disposed on the second rack portion 2300a may include a supporter 1300a disposed on the second rack portion 2300a, a rotator 1200a disposed on the supporting member 1300a, a test board 1100a disposed on the rotator 1200a, and a CPU cooler 1400a disposed on the test board 1100a.

In one or more embodiments, another test device 1000b may be disposed on f the third rack portion 2400a. The test device 1000a disposed on the third rack portion 2400a may include a supporter 1300b disposed on the third rack portion 2400a, a rotator 1200b disposed on the supporting member 1300b, a test board 1100b disposed on the rotator 1200b, and a CPU cooler 1400b disposed on the test board 1100b.

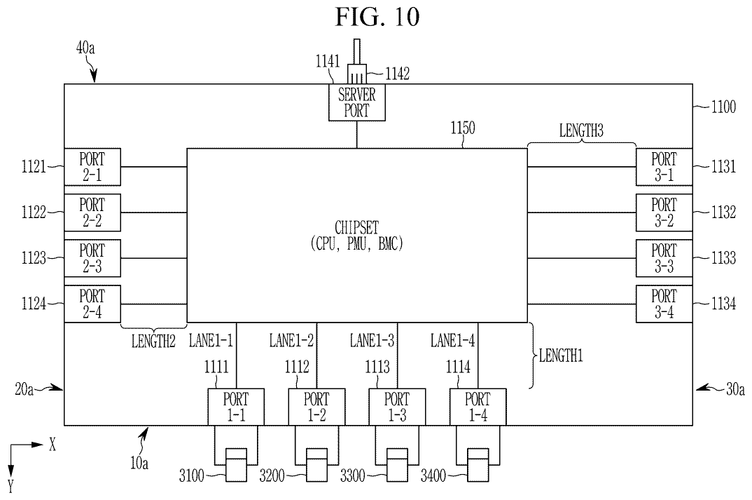

FIG. 10 is a drawing illustrating a test system testing a storage device connected to a first port disposed on a first side surface of the test board, according to one or more embodiments.

Referring to FIG. 10, the test system may include a test device 1000 and a plurality of storage devices 3100-3400. The test device 1000 may test the plurality of storage devices 3100-3400.

In one or more embodiments, the test device 1000 may be disposed in test rack 2000a of FIG. 9. The test board 1100 included in the test device 1000 may be connected to the plurality of storage devices 3100, 3200, 3300, 3400 through the plurality of first ports 1111, 1112, 1113, 1114 disposed on the first side surface 10a. The first side surface 10a of the test board 1100 may face the Y direction.

In one or more embodiments, the plurality of first ports 1111, 1112, 1113, 1114 may be connected to the plurality of first lanes LANE1-1, LANE1-2, LANE1-3, LANE1-4 having a first length LENGTH1 in the Y direction and having the same pattern length. In one or more embodiments, the plurality of first ports 1111, 1112, 1113, 1114 may be respectively connected to the four storage devices, and may operate in connection with the CPU included in the chipset 150 through the plurality of first lanes LANE1-1, LANE1-2, LANE1-3, LANE1-4, which are the interface operation lanes of each storage device, or in connection with more than five operation lanes. In one or more embodiments, a switch, a re-timer, or a re-driver, which improves the characteristics of the data signal or changes the data signal transmission method, may be connected between the CPU included in the chipset 1150 and the storage device. In one or more embodiments, the switch, the re-timer, or the re-driver may change the data signal transmission method from pulse amplitude modulation 2-levels (PAM-2) to PAM-4.

In one or more embodiments, the plurality of storage devices 3100, 3200, 3300, and 3400 may include a first storage device 3100, a second storage device 3200, a third storage device 3300, and a fourth storage device 3400. In one or more embodiments, each of the plurality of storage devices 3100, 3200, 3300, and 3400 may be an solid-state drive (SSD). In one or more embodiments, each of the plurality of storage devices 3100, 3200, 3300, and 3400 may be an SSD used in data centers and vehicles.

The test board 1100 may test the performance of the plurality of storage devices 3100, 3200, 3300, 3400. In one or more embodiments, the CPU included in the chipset 1150 may receive information related to the test operation from an external server through the cable 1142 connected to the server port 1141, and may provide commands for performing the test operation to the first to fourth storage devices 3100-3400 through the plurality of first lanes LANE1-1, LANE1-2, LANE1-3, and LANE1-4. In one or more embodiments, the test operation may be a sequential read operation or a random read operation. In one or more embodiments, the first to fourth storage devices 3100-3400 may perform a test operation and provide signals corresponding to the results of performing the test operation to the CPU included in the chipset 1150. In one or more embodiments, the integrity of the signals, which the first to fourth storage devices 3100-3400 provide to the CPU through the plurality of first lanes LANE1-1, LANE1-2, LANE1-3, LANE1-4 of the first length LENGTH1, may be tested. When the test using the plurality of first lanes LANE1-1, LANE1-2, LANE1-3, LANE1-4 of the first length LENGTH1 is completed, the connections between the first to fourth storage devices 3100-3400 and the plurality of first ports 1111, 1112, 1113, 1114 may be released.

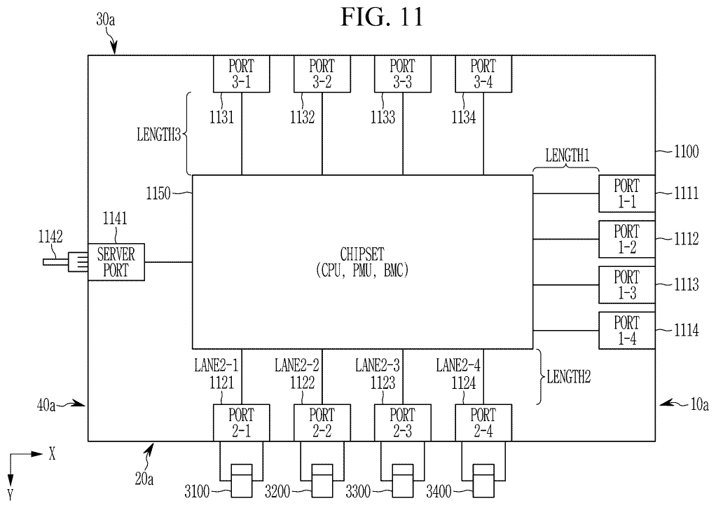

FIG. 11 is a drawing illustrating a test system testing a storage device connected to a second port disposed on a second side surface of the test board, according to one or more embodiments.

Referring to FIG. 11, the test board 1100 in the test device 1000 disposed in the test rack 2000a may be rotated. In one or more embodiments, the test board 1100 may be rotated so that the second side surface 20a of the test board 1100 faces the Y direction. The test board 1100 is rotated so that the second side surface 20a of the test board 1100 faces the Y direction, and then may be connected to the first to fourth storage devices 3100-3400 through the plurality of second ports 1121, 1122, 1123, 1124 placed on the second side surface 20a.

In one or more embodiments, the plurality of second ports 1121, 1122, 1123, 1124 may be connected to the plurality of second lanes LANE2-1, LANE2-2, LANE2-3, LANE2-4 having a second length LENGTH2 in the X direction that is smaller than the first length LENGTH1 in the Y direction and having the same pattern length. In one or more embodiments, the plurality of second ports 1121, 1122, 1123, 1124 may be respectively connected to the four storage devices, and may operate in connection with the CPU included in the chipset 150 through the plurality of first lanes LANE2-1, LANE2-2, LANE2-3, LANE2-4, which are the interface operation lanes of each storage device, or in connection with more than five operation lanes. In one or more embodiments, a switch, a re-timer, or a re-driver, which improves the characteristics of the data signal or changes the data signal transmission method, may be connected between the CPU included in the chipset 1150 and the storage device. In one or more embodiments, the switch, the re-timer, or the re-driver may change the data signal transmission method from PAM-2 to PAM-4.

The first to fourth storage devices 3100-3400 may provide signals the CPU in chipset 1150 through plurality of second lanes LANE2-1, LANE2-2, LANE2-3, LANE2-4 of a second length LENGTH2. While the first to fourth storage devices 3100-3400 provide signals to the CPU in chipset 1150 through the plurality of second lanes LANE2-1, LANE2-2, LANE2-3, LANE2-4, the signal integrity of the first to fourth storage devices 3100-3400 may be tested.

When the test using the plurality of first lanes LANE2-1, LANE2-2, LANE2-3, LANE2-4 of the second length LENGTH2 is completed, the connections between the first to fourth storage devices 3100-3400 and the plurality of second ports 1121, 1122, 1123, 1124 may be released.

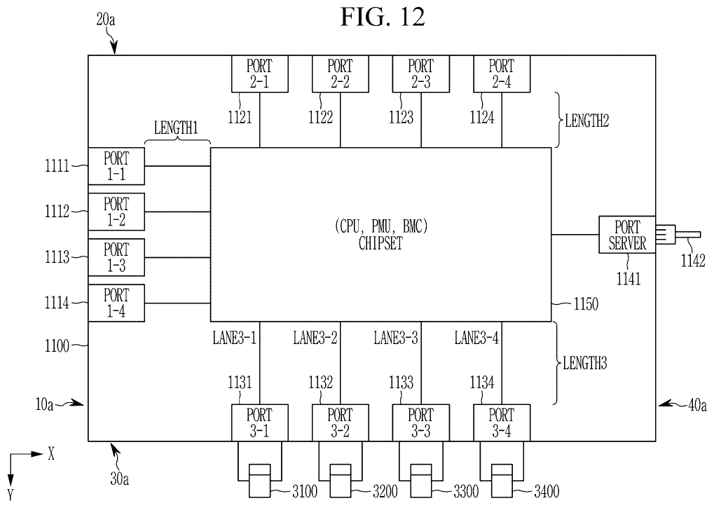

FIG. 12 is a drawing illustrating a test system testing a storage device connected to a third port disposed on a third side surface of the test board, according to one or more embodiments.

Referring to FIG. 12, the test board 1100 in the test device 1000 disposed in the test rack 2000a may be rotated so that the third side surface 30a of the test board 1100 faces the Y direction. The test board 1100 is rotated so that the third side surface 30a of the test board 1100 faces the Y direction, and then may be connected to the first to fourth storage devices 3100-3400 through the plurality of third ports 1131, 1132, 1133, 1134 placed on the third side surface 30a.

In one or more embodiments, the plurality of third ports 1131, 1132, 1133, 1134 may be connected to the plurality of third lanes LANE3-1, LANE3-2, LANE3-3, LANE3-4 having a third length LENGTH3 in the Y direction greater than the first length LENGTH1 and the having same pattern length. In one or more embodiments, the plurality of third ports 1131, 1132, 1133, 1134 may be respectively connected to the four storage devices, and may operate in connection with the CPU included in the chipset 150 through the plurality of third lanes LANE3-1, LANE3-2, LANE3-3, LANE3-4, which are the interface operation lanes of each storage device, or in connection with more than five operation lanes. In one or more embodiments, a switch, a re-timer, or a re-driver, which improves the characteristics of the data signal or changes the data signal transmission method, may be connected between the CPU included in the chipset 1150 and the storage device. In one or more embodiments, the switch, the re-timer, or the re-driver may change the data signal transmission method from PAM-2 to PAM-4.

The first to fourth storage devices 3100-3400 may provide signals the CPU in chipset 1150 through plurality of third lanes LANE3-1, LANE3-2, LANE3-3, LANE3-4 of the third length LENGTH3. While the first to fourth storage devices 3100-3400 provide signals to the CPU in chipset 1150 through the plurality of third lanes LANE3-1, LANE3-2, LANE3-3, LANE3-4, the signal integrity of the first to fourth storage devices 3100-3400 may be tested.

When the test using the plurality of third lanes LANE3-1, LANE3-2, LANE3-3, LANE3-4 of the third length LENGTH3 is completed, the connections between the first to fourth storage devices 3100-3400 and the plurality of third ports 1131, 1132, 1133, 1134 may be released.

In one or more embodiments, the test device 1000 may rotate the test board 1100 using the rotator 1200 so that the first side surface 10a, the second side surface 20a, or the third side surface 30a of the test board 1100 face the Y direction. In one or more embodiments, the test device 1000 may test storage devices which may be connected to a CPU through lanes or channels of various lengths in data center and vehicles, using a plurality of ports connected to a plurality of lanes of different lengths and disposed on different side surfaces.

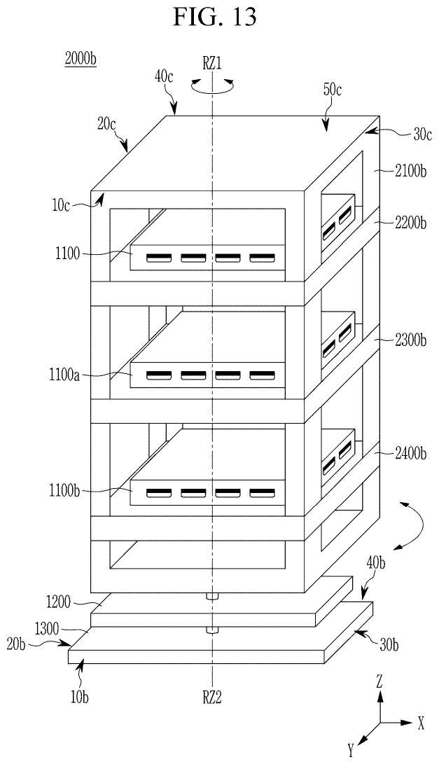

FIG. 13 is a drawing illustrating a test board disposed on a rotating test rack according to one or more embodiments.

Referring to FIG. 13, a plurality of test devices 1100, 1100a, 1100b may be disposed in the test rack 2000b. The test rack 2000b may include a main body case 2100b, a plurality of rack portions 2200b, 2300b, 2400b, a rotator 1200, and a supporter 1300. The main body case 2100b may have a plurality of open side surfaces. In one or more embodiments, the main body case 2100b may have a first side surface 10c, a second side surface 20c, a third side surface 30c, and a fourth side surface 40c. In one or more embodiments, the first side surface 10c, the second side surface 20c, and the third side surface 30c of the main body case 2100b may be the open side surfaces.

The plurality of rack portions 2200b, 2300b, 2400b may be disposed inside the main body case 2100a. The plurality of rack portions 2200b, 2300b, 2400b may include first rack portion 2200b, second rack portion 2300b, and third rack portion 2400b. The plurality of test devices 1100, 1100a, 1100b may be disposed on the plurality of rack portions 2200b, 2300b, 2400b.

The rotator 1200 may be disposed below the main body case 2100b. The supporter 1300 may be disposed below the rotator 1200.

In one or more embodiments, the rotator 1200 may rotate the main body case 2100b. In one or more embodiments, the rotator 1200 is perpendicular to a upper surface 50c of the main body case 2100b, and may rotate the main body case 2100b with respect to a rotation axis RZ1-RZ2 parallel to the Z direction. In one or more embodiments, the rotator 1200 may rotate the main body case 2100b so that the first side surface 10c, the second side surface 20c, or the third side surface 30c of the main body case 2100b face the Y direction.

In one or more embodiments, the first side surface 10c, the second side surface 20c, or the third side surface 30c of the main body case 2100b may be aligned to face the same direction as the first side surface 10b of the supporter 1300. The first side surface 10b of the supporter 1300 may extend in the X direction. The second side surface 20b and the third side surface 30b of the supporter 1300 may extend in the Y direction.

In one or more embodiments, the first side surface 10c of the main body case 2100b and the first side surface 10b of the supporter 1300 may be aligned to face a direction which is perpendicular to the rotation axis RZ1-RZ2 and parallel to the upper surface 50c of the main body case 2100b. In one or more embodiments, the direction which is perpendicular to the rotation axis RZ1-RZ2 and parallel to the upper surface 50c of the main body case 2100b may be the Y direction. In one or more embodiments, the second side surface 20c of the main body case 2100b and the first side surface 10b of the supporter 1300 may be aligned to face a direction which is perpendicular to the rotation axis RZ1-RZ2 and parallel to the upper surface 50c of the main body case 2100b. In one or more embodiments, the third side surface 30c of the main body case 2100b and the first side surface 10b of the supporter 1300 may be aligned to face a direction which is perpendicular to the rotation axis RZ1-RZ2 and parallel to the upper surface 50c of the main body case 2100b.

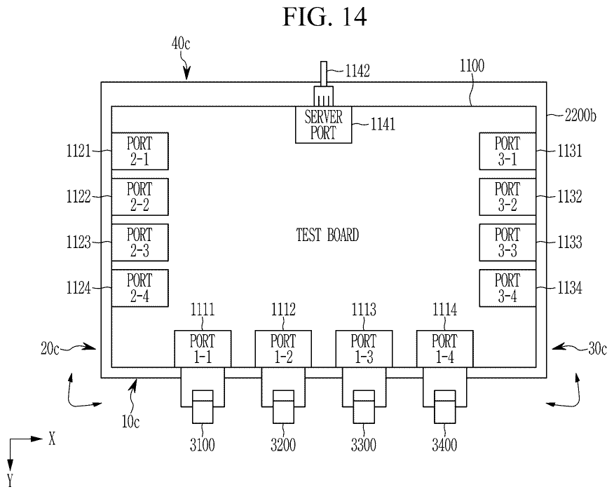

FIG. 14 is a drawing illustrating a storage device connected to a test board disposed on a rotating test rack, according to one or more embodiments.

Referring to FIG. 14, the test board 1100 may be disposed the test rack 2000b of FIG. 13. The test board 1100 may be disposed on the first rack portion 2200b. The main body case 2100b may be aligned so that the first side surface 10c of the main body case faces the Y direction.

In one or more embodiments, the test board 1100 has a plurality of first ports 1111, 1112, 1113, 1114 connected to the plurality of first lanes having a first length, a plurality of second ports 1121, 1122, 1123, 1124 connected to a plurality of second lanes having a second length smaller than the first length, a plurality of third ports 1131, 1132, 1133, 1134 connected to plurality of third lanes having a third length greater than the first length, and server port 1141.

In one or more embodiments, the plurality of first ports 1111, 1112, 1113, 1114 included in the test board 1100 may be aligned to face the Y direction. The plurality of first ports 1111, 1112, 1113, 1114 may be connected to the first to fourth storage devices 3100-3400. Using the plurality of first ports 1111, 1112, 1113, 1114 connected to the first lanes of the first length, the integrity of the signals of the first to fourth storage devices 3100-3400 may be tested.

In one or more embodiments, the main body case 2100b may be rotated so that the second side surface 20c of main body case 2100b faces the Y direction. When the second side surface 20c of the main body case 2100b faces the Y direction, the plurality of second ports 1121, 1122, 1123, 1124 included in the test board 1100 may be aligned to face the Y direction. The plurality of second ports 1121, 1122, 1123, 1124 may be connected to the first to fourth storage devices 3100-3400. Using the plurality of second ports 1121, 1122, 1123, 1124 connected to the second lanes of the second length, the integrity of the signals of the first to fourth storage devices 3100-3400 may be tested.

In one or more embodiments, the main body case 2100b may be rotated so that the third side surface 30c of main body case 2100b faces the Y direction. If the third side surface 30c of the main body case 2100b faces the Y direction, the plurality of third ports 1131, 1132, 1133, 1134 included in the test board 1100 may be aligned to face the Y direction. The plurality of third ports 1131, 1132, 1133, 1134 may be connected to the first to fourth storage devices 3100-3400. Using the plurality of third ports 1131, 1132, 1133, 1134 connected to the third lanes of the third length, the integrity of the signals of the first to fourth storage devices 3100-3400 may be tested.

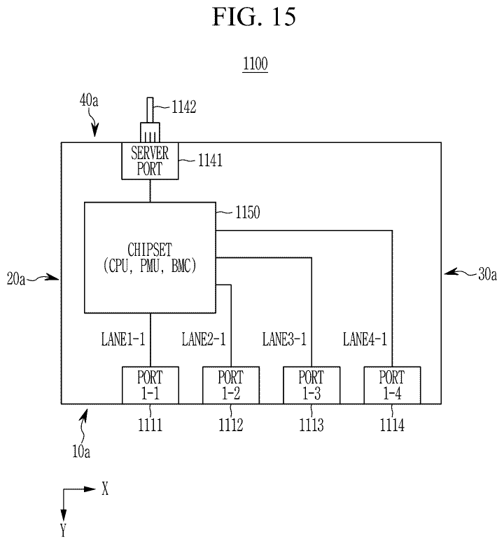

FIG. 15 is a drawing illustrating a test board according to one or more embodiments in which a plurality of ports connected to a plurality of lanes having different lengths are disposed on one side surface.

Referring to FIG. 15, the test board 1100 may include chipset 1150, 1-1st port 1111, 1-2nd port 1112, 1-3rd port 1113, 1-4th port 1114, and server port 1141. In one or more embodiments, the test board 1100 may include a plurality of ports connected to the CPU included in the chipset 1150 through a plurality of lanes disposed on one of the plurality of side surfaces and having different lengths.

In one or more embodiments, 1-1st port 1111, 1-2nd port 1112, 1-3rd port 1113, and 1-4th port 1114 may be disposed on the first side surface 10a of the test board 1100. In one or more embodiments, 1-1st port 1111 may be connected to the CPU included in the chipset 1150 through 1-1st lane LANE1-1 of the first length. The 1-2nd port 1112 may be connected to the CPU included in the chipset 1150 through the 2-1st lane LANE2-1 having a second length greater than the first length. The 1-3rd port 1113 may be connected to the CPU included in the chipset 1150 through the 3-1st lane LANE3-1 having a third length greater than second length. The 1-4th port 1114 may be connected to the CPU included in the chipset 1150 through the fourth first lane LANE4-1 having a fourth length greater than the third length.

FIG. 15 illustrates an example that a plurality of ports connected to a plurality of lanes having different lengths are disposed on the first side surface 10a of the test board 1100, but embodiments are not limited thereto, and, for example, the plurality of ports connected to plurality of lanes having different lengths may be disposed not only on the first side surface 10a but also on the second side surface 20a and the third side surface 30a of the test board 1100.

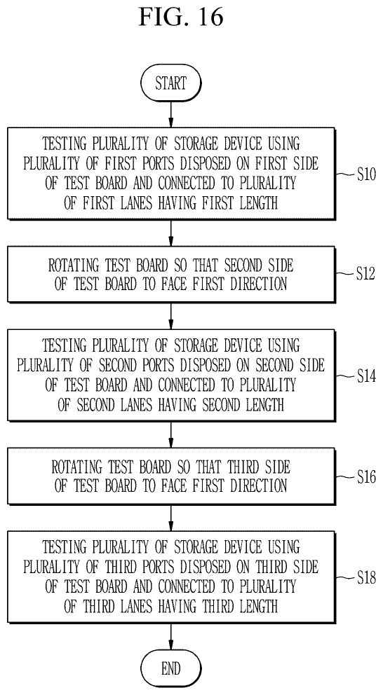

FIG. 16 is a flowchart illustrating a test device for testing a storage device according to one or more embodiments.

Referring to FIG. 16, the test device 1000 may test the plurality of storage devices, using a plurality of first ports connected to a plurality of first lanes disposed on the first side surface of the test board 1100 and having a first length. The first side surface of the test board 1100 may face a first direction. The first direction may be a direction parallel to the upper surface of the test board 1100. The first direction may be Y direction of FIG. 1. In one or more embodiments, the locker 1500 may be positioned at one end of the third side surface of the supporter 1300 during the plurality of storage devices being tested using the plurality of first ports. When the locker 1500 is positioned at one end of the third side surface of the supporter 1300, the rotation of the test board 1100 and the rotator 1200 may be prevented. In one or more embodiments, when the test of the plurality of storage devices using the plurality of first ports is completed, the connection between the plurality of storage devices and the plurality of first ports may be released. In one or more embodiments, when the test of the plurality of storage devices using the plurality of first ports is completed, the position of the locker 1500 may be moved from one end to the other end of the third side surface of the supporter 1300. In one or more embodiments, when the locker 1500 is positioned at the other end of the third side surface of the supporter 1300, rotation of the test board 1100 and the rotator 1200 may be allowed.

In S12, the test device 1000 may rotate the test board 1100 so that the second side surface of the test board 1100 faces the first direction. In one or more embodiments, the test board 1100 may be rotated so that the second side surface of the test board 1100 faces the first direction as the rotator 1200 rotates. In one or more embodiments, when the second side surface of the test board 1100 is rotated to face the first direction, the position of the locker 1500 may be moved from the other end of the third side surface of the supporter 1300 to the one end. When the locker 1500 is positioned at one end of the third side surface of the supporter 1300, the rotation of the test board 1100 and the rotator 1200 may be prevented.

In S14, the test device 1000 may test the plurality of storage device using the plurality of second ports connected to the plurality of second lane disposed on the second side surface of the test board 1100 and having a second length. The second length may be smaller than the first length. In one or more embodiments, when the test of the plurality of storage devices using the plurality of second ports is completed, the connection between the plurality of storage devices and the plurality of second ports may be released. In one or more embodiments, when the test of the plurality of storage devices using the plurality of second ports is completed, the position of the locker 1500 may be moved from one end to the other end of the third side surface of the supporter 1300, and then rotation of the test board 1100 and the rotator 1200 may be allowed.

In S16, the test device 1000 may rotate the test board 1100 so that the third side surface of the test board 1100 faces the first direction. In one or more embodiments, the test board 1100 may be rotated so that the third side surface of the test board 1100 faces the first direction as the rotator 1200 rotates. In one or more embodiments, when the third side surface of the test board is rotated to face the first direction, the position of the locker 1500 is moved from the other end of the third side surface of the supporter to the one end, and then rotation of the test board 1100 and rotator 1200 may be prevented.

In S18, the test device 1000 may test the plurality of storage devices using the plurality of third ports connected to the plurality of third lanes disposed on the third side surface of the test board 1100 and having a third length. The third length may be greater than the first length. In one or more embodiments, when the test of the plurality of storage devices using the plurality of third ports is completed, the connection between the plurality of storage devices and the plurality of third ports may be released. In one or more embodiments, when the test of the plurality of storage devices using the plurality of third ports is completed, the position of the locker 1500 may be moved from one end to the other end of the third side surface of the supporter 1300, and then rotation of the test board 1100 and the rotator 1200 may be allowed.

While embodiments have been described with reference to the figures, it will be understood by those of ordinary skill in the art that various changes in form and details may be made therein without departing from the spirit and scope as defined by the following claims and their equivalents.

What is claimed is:

1. A test device comprising:
a supporter;
a test board on the supporter, the test board comprising a central processing unit (CPU) and a plurality of ports connected to the CPU through a plurality of lanes respectively on different side surfaces of the test board and having different lengths; and
a rotator between the supporter and the test board, the rotator being configured to rotate the test board with respect to a rotation axis perpendicular to an upper surface of the test board.

2. The test device of claim 1, wherein a first port of the plurality of ports is connected to the CPU through a first lane having a first length among the plurality of lanes,
wherein a second port of the plurality of ports is connected to the CPU through a second lane having a second length smaller than the first length among the plurality of lanes, and
wherein a third port of the plurality of ports is connected to the CPU through a third lane having a third length greater than the first length among the plurality of lanes.

3. The test device of claim 2, wherein the first port is on a first side surface of the test board,
wherein the second port is on a second side surface of the test board, and
wherein the third port is on a third side surface of the test board.

4. The test device of claim 3, wherein the first side surface of the test board, the second side surface of the test board, or the third side surface of the test board is aligned with a first side surface of the supporter in a direction perpendicular to the rotation axis and parallel to the upper surface of the test board.

5. The test device of claim 4, further comprising:
a locker on a second side surface of the supporter, the locker being configured to prevent or allow rotation of the test board.

6. The test device of claim 1, further comprising:
a CPU heatsink on the CPU, and
wherein the rotator comprises an auxiliary heatsink connected to the CPU heatsink through a heat pipe.

7. The test device of claim 1, wherein the rotator comprises an internal fan on a side of the CPU.

8. The test device of claim 1, further comprising:
a thermal pad between the test board and the rotator.

9. The test device of claim 1, wherein the test board comprises a power management unit (PMU) below the CPU, or a baseboard management controller (BMC) on a side of the CPU.

10. A test system comprising:
a storage device; and
a test device comprising a plurality of ports on different side surfaces of a test board and connected to a plurality of lanes having different lengths, respectively, the test device being configured to test the storage device sequentially connected to the plurality of ports.

11. The test system of claim 10, wherein the test device comprises:
a test board comprising a central processing unit (CPU) connected to the plurality of ports through the plurality of lanes, respectively, and a power management unit (PMU) on a side of the CPU.

12. The test system of claim 11, wherein the test device comprises:
a supporter on a side of the test board; and
a rotator between the supporter and the test board, the rotator being configured to rotate the test board with respect to a rotation axis perpendicular to an upper surface of the test board.

13. The test system of claim 12, further comprising:
a CPU cooler on the CPU, and
wherein the rotator comprises an auxiliary heatsink connected to the CPU cooler through a heat pipe.

14. The test system of claim 12, wherein a first port of the plurality of ports is on a first side surface of the test board,
wherein a second port of the plurality of ports is on a second side surface of the test board, and
wherein a third port of the plurality of ports is on a third side surface of the test board.

15. The test system of claim 14, wherein the first side surface of the test board, the second side surface of the test board, or the third side surface of the test board faces the same direction as a first side surface of the supporter.

16. The test system of claim 14, wherein the first port is connected to the CPU through a first lane having the first length among the plurality of lanes,
wherein the second port is connected to the CPU through a second lane having a second length smaller than the first length, among the plurality of lanes, and
wherein the third port is connected to the CPU through a third lane having a third length greater than the first length, among the plurality of lanes.

17. A test rack comprising:
a supporter;
a main body case comprising a plurality of open side surfaces, the main body case being on the supporter;
a rack portion included in the main body case and comprising a test board that comprises a plurality of ports respectively on the plurality of open side surfaces and respectively connected to a plurality of lanes having different lengths; and
a rotator between the supporter and the main body case, and being configured to rotate the main body case with respect to a rotation axis perpendicular to an upper surface of the main body case.

18. The test rack of claim 17, wherein a first port of the plurality of ports is on a first side surface of the plurality of side surfaces,
wherein a second port of the plurality of ports is on a second side surface of the plurality of side surfaces, and
wherein a third port of the plurality of ports is disposed on a third side surface of the plurality of side surfaces.

19. The test rack of claim 18, wherein the first side surface, the second side surface, or the third side surface of the main body case faces the same direction as a first surface of the supporter.

20. The test rack of claim 17, wherein the test board comprises:
a central processing unit (CPU) connected to the plurality of ports through the plurality of lanes;
a power management unit (PMU) on a side of the CPU; and
a baseboard management controller on a side of the CPU.
